(19) United States
(12) Patent Application Publication
(10) Pub. No.: US 2015/0194382 A1
(43) Pub. Date: Jul. 9, 2015

(54) INTERCONNECT AND METHOD OF FABRICATING THE SAME

(71) Applicant: MACRONIX International Co., Ltd., Hsinchu (TW)

(72) Inventors: Cheng-Fen Lai, Hsinchu (TW); Meng-Shien Hsieh, Hsinchu (TW); Shiau-Lian Liu, Hsinchu (TW)

(73) Assignee: MACRONIX International Co., Ltd., Hsinchu (TW)

(21) Appl. No.: 14/146,911

(22) Filed: Jan. 3, 2014

(51) Int. Cl. H01L 23/528; H01L 21/768; H01L 23/532

(52) U.S. Cl. CPC H01L 23/528; H01L 23/53228; H01L 23/53214; H01L 23/53257; H01L 23/53271; H01L 23/53219; H01L 23/53233; H01L 21/7684

(57) ABSTRACT

Provided is a method of fabricating an interconnect including the following steps. A conductive plug and a dielectric layer are provided, wherein a surface of the conductive plug and the surface of the dielectric layer substantially form a planar surface. A chemical mechanical polishing process is performed to the planar surface, wherein a chemical removal rate of the dielectric layer is greater than a chemical removal rate of the conductive plug. A conductive line is formed to electrically connect the conductive plug.

### BACKGROUND OF THE INVENTION

1. Field of the Invention

The invention relates to an interconnect and a method of fabricating the same. More particularly, the invention relates to an interconnect having a protruding conductive plug and a method of fabricating the same.

2. Description of Related Art

In the interconnect of a conventional semiconductor device, a conductive line is formed on a conductive plug to electrically connect the conductive plug. However, after the conductive line is etched, a void may be present between the conductive plug and the conductive line, which may result in issues such as solvents seeping into the seam of the conductive plug and causing the occurrence of an electrochemical reaction between the conductive line and the conductive plug. As a result, a solution to preventing the presence of a void between the conductive plug and the conductive line is urgently needed.

### SUMMARY OF THE INVENTION

The invention provides an interconnect capable of preventing the presence of a void between a conductive plug and a conductive line.

The invention provides an interconnect capable of preventing solvents from seeping into the seam of a conductive plug, thereby preventing the occurrence of an electrochemical reaction between a conductive line and the conductive plug.

The invention provides a method of fabricating an interconnect including the following steps. A conductive plug and a dielectric layer are provided, wherein a surface of the conductive plug and the surface of the dielectric layer substantially form a planar surface. A chemical mechanical polishing process is performed to the planar surface, wherein a chemical removal rate of the dielectric layer is greater than a chemical removal rate of the conductive plug. A conductive line is formed to electrically connect the conductive plug.

In an embodiment of the invention, the conductive plug forms a protrusion beyond the dielectric layer after the chemical mechanical polishing process is performed.

In an embodiment of the invention, an inclination angle of the protrusion is 10 degrees or greater.

In an embodiment of the invention, an aspect ratio of the protrusion is ranged from 0.15 to 0.45.

In an embodiment of the invention, the protrusion includes a top surface and a sidewall.

In an embodiment of the invention, a duration of the chemical mechanical polishing process is 20 seconds or greater.

In an embodiment of the invention, a barrier layer is further formed between the conductive plug and the conductive line.

The invention provides a method of fabricating an interconnect including the following steps. A hole is formed in a dielectric layer. A conductive layer is formed on the dielectric layer filling the hole. A first chemical mechanical polishing process is performed to the first conductive layer so as to form a conductive plug in the dielectric layer, wherein a surface of the conductive plug and a surface of the dielectric layer substantially form a planar surface, wherein a chemical removal rate of the dielectric layer is lower than a chemical removal rate of the conductive layer. A second chemical mechanical polishing process is performed to the planar surface so that the conductive plug forms a protrusion beyond the dielectric layer, wherein a chemical removal rate of the dielectric layer is greater than a chemical removal rate of the conductive plug. A conductive line is formed to electrically connect the conductive plug.

In an embodiment of the invention, an inclination angle of the protrusion is 10 degrees or greater.

In an embodiment of the invention, an aspect ratio of the protrusion is ranged from 0.15 to 0.45.

In an embodiment of the invention, the protrusion includes a top surface and a sidewall.

In an embodiment of the invention, a duration of the second chemical mechanical polishing process is 20 seconds or greater.

In an embodiment of the invention, a barrier layer is further formed between the conductive plug and the conductive line.

The invention provides an interconnect including a dielectric layer; a conductive plug disposed in the dielectric layer, wherein the conductive plug has a protrusion beyond the dielectric layer, wherein an inclination angle of the protrusion is 10 degrees or greater; and a conductive line disposed on and being electrically connected to the conductive plug.

In an embodiment of the invention, an aspect ratio of the protrusion is ranged from 0.15 to 0.45.

In an embodiment of the invention, the protrusion includes a top surface and a sidewall.

In an embodiment of the invention, a material of the conductive plug includes tungsten, copper, polysilicon or aluminum.

In an embodiment of the invention, a material of the conductive line includes aluminum, copper, or an alloy thereof.

In an embodiment of the invention, a barrier layer further disposed between the conductive plug and the conductive line.

In an embodiment of the invention, one material of the barrier layer is a metallic material, such as titanium, tantalum, titanium nitride, or tantalum nitride

Based on the above, the interconnect of the invention includes a conductive plug protruding beyond the dielectric layer. The protrusion of the conductive plug increases the contact area of the conductive plug and allows the conductive plug to be completely covered by the conductive line formed on the conductive plug, thereby preventing the presence of a void between the conductive plug and the conductive line. Moreover, when the conductive plug has better coverage, solvents do not readily seep into the seam of the conductive plug, thereby preventing the occurrence of an electrochemical reaction between the conductive line and the conductive plug.

It is to be understood that both the foregoing general description and the following detailed description are exemplary, and are not intended to limit the scope of the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F illustrate schematic diagrams of a process of a method of fabricating an interconnect according to an embodiment of the invention.

FIG. 2A to FIG. 2F illustrate schematic diagrams of a process of a method of fabricating an interconnect according to another embodiment of the invention.

FIG. 3A to FIG. 3F illustrate schematic diagrams of a process of a method of fabricating an interconnect according to yet another embodiment of the invention.

FIG. 4A to FIG. 4F illustrate schematic diagrams of a process of a method of fabricating an interconnect according to still yet another embodiment of the invention.

FIG. 5 is a schematic diagram of the protrusion of a conductive plug according to an embodiment of the invention.

FIG. 6 is a schematic diagram of the protrusion of a conductive plug according to another embodiment of the invention.

### DESCRIPTION OF THE EMBODIMENTS

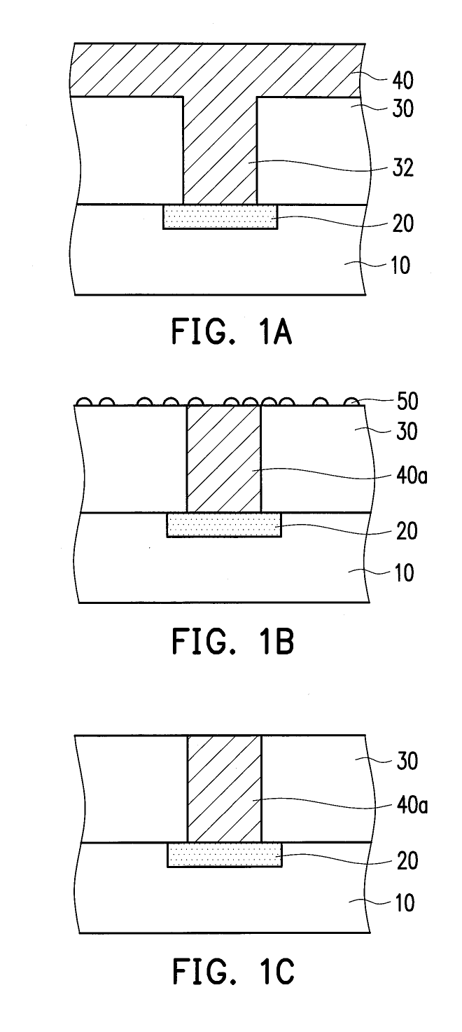

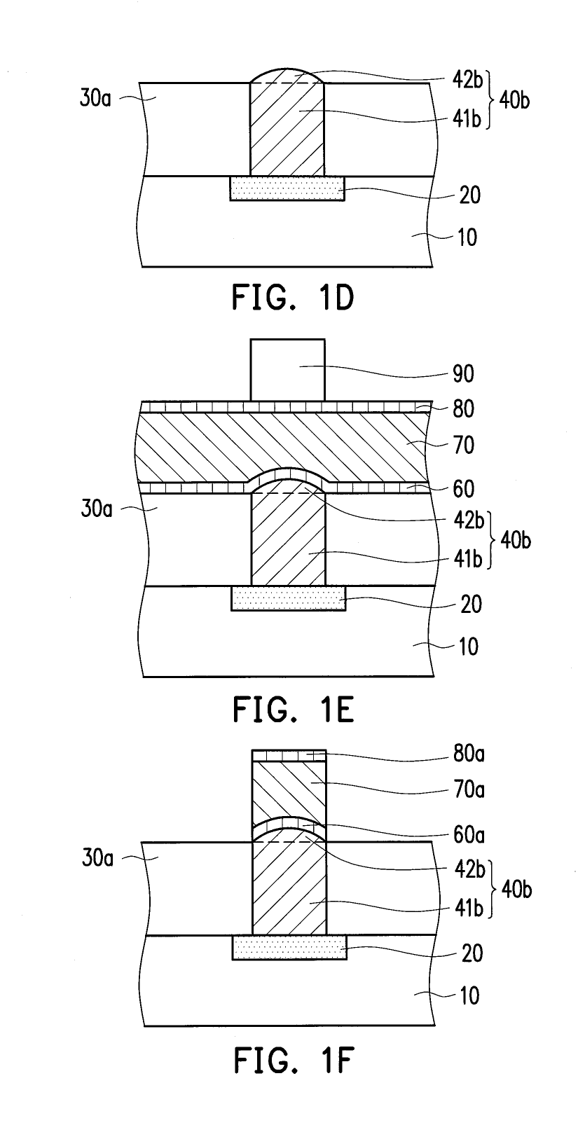

FIG. 1A to FIG. 1F illustrate schematic diagrams of a process of a method of fabricating an interconnect according to an embodiment of the invention.

Referring to FIG. 1A, in the present embodiment, a substrate 10 is provided. The substrate 10 can be, for instance, a semiconductor substrate or a dielectric layer. A conductive region 20 is disposed in the substrate 10. The conductive region 20 can be, for instance, a source region, a drain region, a gate electrode, or a conductive line. A dielectric layer 30 is disposed on the substrate 10. The material of the dielectric layer 30 includes, for instance, silicon oxide, a low-k material, a suitable insulating material, or a combination thereof. The dielectric layer 30 is formed by, for instance, a chemical vapor deposition. The thickness of the dielectric layer 30 is ranged from, for instance, 3000 Å to 7000 Å. A hole 32 is formed in the dielectric layer 30, exposing the conductive region 20 therebelow. The hole 32 is formed by, for instance, a lithography process and an etching process. A conductive layer 40 is formed on the dielectric layer 30, thereby filling the hole 32. The material of the conductive layer 40 includes tungsten, copper, polysilicon or aluminium. The conductive layer 40 is formed by, for instance, a physical vapor deposition such as sputtering.

Next, referring to FIGS. 1B and 1C, a first chemical mechanical polishing (CMP) process is performed on the conductive layer 40 to form a conductive plug 40a in the dielectric layer 30. In an embodiment, the first CMP process may include two steps. The first step of the first CMP process is performed to form the conductive plug 40a in the dielectric layer 30 as shown in FIG. 1B. At this point, a plurality of residues 50 is present on the surface of the dielectric layer 30, and the surface of the conductive plug 40a and the surface of the dielectric layer 30 are substantially planar. Therefore, after an end point is detected, the second step of the first CMP process is further performed to remove the residues 50 as shown in FIG. 1C. For the first CMP process of FIG. 1B and FIG. 1C, the chemical removal rate of the dielectric layer 30 is lower than the chemical removal rate of the conductive layer 40. In other words, the conductive layer 40 is removed faster than the dielectric layer 30 to achieve the substantially planar surface of the conductive plug 40a and the dielectric layer 30. In an embodiment, for the first CMP process, the chemical removal rate of the dielectric layer 30 in the first step of the first CMP process is faster than or the same as that in the second step. In an embodiment, the slurry used in the first step of the first CMP process contains, for instance, including abrasive of Al₂O₃ and SiO₂ (such as available from W2000 or W7300 manufactured by Cabot Microelectronics Corporation). The pH of the first step of the first CMP process is, for instance, 5˜6. The removal rate of the first step of the first CMP process is, for instance, 2950˜3950 Å/min. The duration of the first step of the first CMP process is between, for instance, 15 seconds and 35 seconds. The slurry used in the second step of the first CMP process contains, for instance, abrasive of Al₂O₃ and SiO₂ (such as available form W2000 or W7300 manufactured by Cabot Microelectronics Corporation). The pH of the second step of the first CMP process is, for instance, 5˜6. The removal rate of the second step of the first CMP process is, for instance, 2950˜3950 Å/min. The duration of the second step of the first CMP process is between, for instance, 8 seconds and 16 seconds.

Next, referring to FIG. 1D, a second CMP process is performed to remove a portion of the dielectric layer 30, leaving a dielectric layer 30a. After the second CMP process is performed, the conductive plug 40a is formed into a conductive plug 40b. The conductive plug 40b includes a body 41b and a protrusion 42b. For the second CMP process, the chemical removal rate of the dielectric layer 30 is greater than the chemical removal rate of the conductive layer 40. In other words, the dielectric layer 30 is removed faster than the conductive layer 40 such that the conductive plug 40b can form the protrusion 42b beyond the dielectric layer 30a after the second CMP process is performed. The slurry used in the second CMP process contains, for instance, ILD3013 manufactured by Cabot Microelectronics Corporation. The pH of the second CMP process is, for instance, 5˜7. In an example, the removal rate of the second CMP process is 150˜250 Å/min, such as 200 Å/min. The duration of the second CMP process is between, for instance, 20 seconds and 60 seconds. In an embodiment, durations of the first and the second step of the first CMP process are respectively 25 and 12 seconds, and a duration of the second CMP process is 40 seconds.

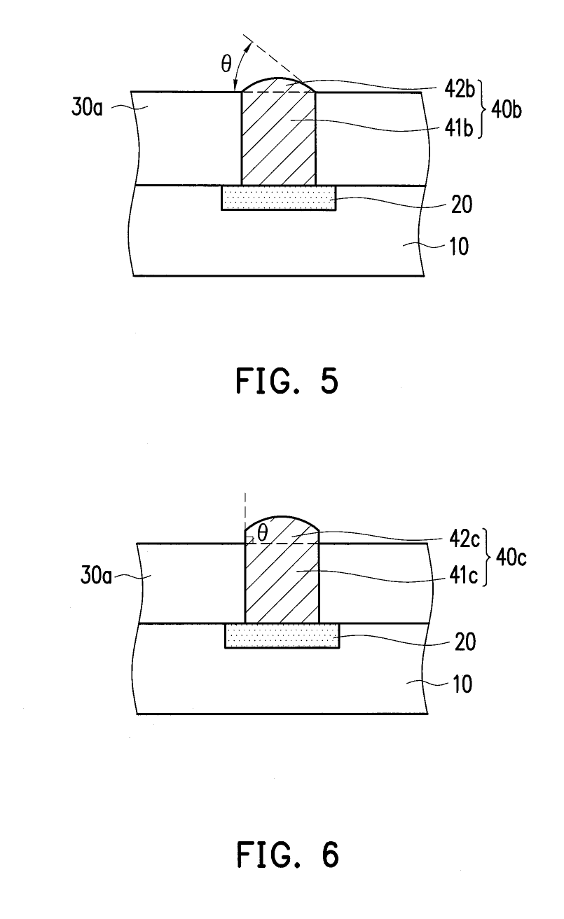

FIG. 5 is a schematic diagram of the protrusion of a conductive plug according to an embodiment of the invention.

Referring to FIG. 5, the conductive plug 40b includes the body 41b and the protrusion 42b. The body 41b of the protrusion 42b is located in the dielectric layer 30, and the protrusion 42b is located on the body 41b and protrudes beyond the dielectric layer 30. The top surface of the protrusion 42b is, for instance, dome shaped. The aspect ratio and an inclination angle θ of the protrusion 42b depend directly on the duration of the CMP process. In particular, the inclination angle θ is the angle between the top surface of the protrusion 42b and the surface level of the dielectric layer 30a at which the protrusion 42b occurs. The longer the duration of the CMP process, the greater the inclination angle θ and the aspect ratio of the protrusion 42b. In an embodiment, the inclination angle θ of the protrusion 42b is, for instance, 10 degrees or greater, and the aspect ratio of the protrusion 42b is ranged from, for instance, 0.15 to 0.45.

Next, referring to FIG. 1E and FIG. 1F, a first barrier layer 60a, a conductive line 70a, and a second barrier layer 80a are formed on the conductive plug 40b in sequence from the bottom up to electrically connect the conductive plug 40b. The direction of extension of the conductive line 70a is, for instance, perpendicular to the direction of extension of the conductive plug 40b. The first barrier layer 60a can improve the adhesion between the conductive line 70a and the conductive plug 40b. The forming method of the first barrier layer 60a, the conductive line 70a, and the second barrier layer 80a includes, for instance, depositing a first barrier layer 60, a conductive line 70, and a second barrier layer 80 on the conductive plug 40b in sequence from the bottom up, then performing a lithography process to form a photoresist pattern 90 on the second barrier layer 80, and then performing an etching process to etch the second barrier layer 80, the conductive line 70 and the first barrier layer 60 using the photoresist pattern 90 as an etching mask. The material of each of the first barrier layer 60 and the second barrier layer 80 includes titanium nitride, or titanium. The material of the conductive line 70 includes aluminium, copper, or an alloy thereof. The thickness of each of the first barrier layer 60 and the second barrier layer 80 is ranged from, for instance, 25 Å to 200 Å. The thickness of the conductive line 70 is ranged from, for instance, 1500 Å to 8500 Å. Each of the first barrier layer 60, the conductive line 70, and the second barrier layer 80 is formed by, for instance, a chemical vapor deposition or a physical vapor deposition such as sputtering.

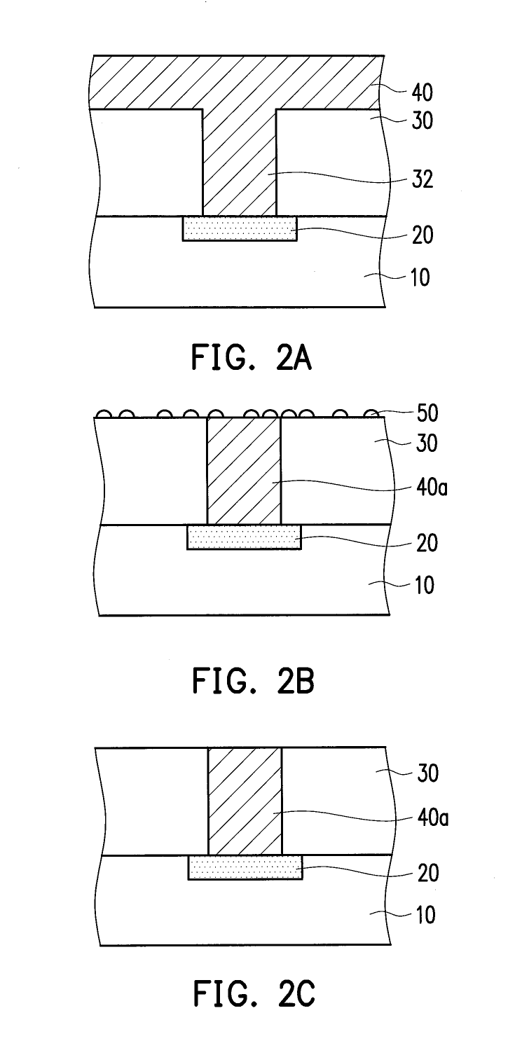

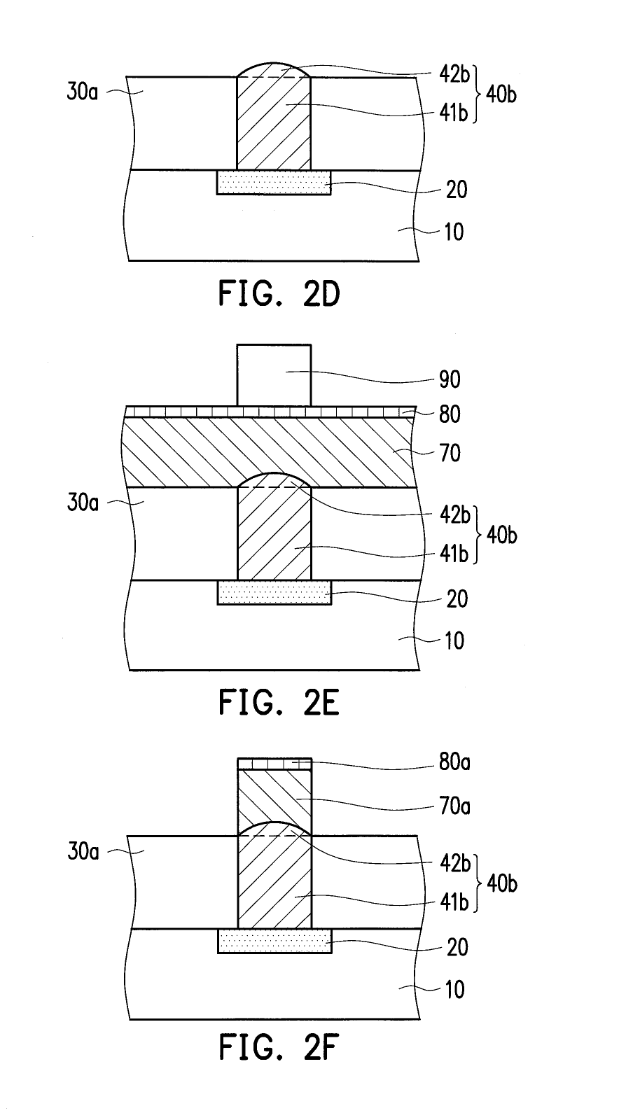

FIG. 2A to FIG. 2F illustrate schematic diagrams of a process of a method of fabricating an interconnect according to another embodiment of the invention.

In the present embodiment, an effect for preventing short-circuit can be further provided. When the first barrier layer 60a is present, the width of the first barrier layer 60a may be greater than the width of the conductive line 70a due to different etching rates of the first barrier layer 60 and the conductive line 70. As a result, two adjacent first barrier layer 60a may come in contact with each other and cause a short-circuit. The steps and conditions of FIG. 2A to FIG. 2D are the same as the steps and conditions of FIG. 1A to FIG. 1D and are not repeated herein. The present embodiment is different from the embodiment of FIG. 1A to FIG. 1F in that in the present embodiment, the first barrier layer 60a is omitted. In other words, in the present embodiment, only the conductive line 70a and the second barrier layer 80a are formed on the conductive plug 40b in sequence from the bottom up as shown in FIG. 2E and FIG. 2F to electrically connect the conductive plug 40b. The direction of extension of the conductive line 70a is, for instance, perpendicular to the direction of extension of the conductive plug 40b. The forming method of each of the conductive line 70a and the second barrier layer 80a is as described above and is not repeated herein. In the present embodiment, the first barrier layer 60a is omitted to prevent a short-circuit between any two adjacent first barrier layer 60a.

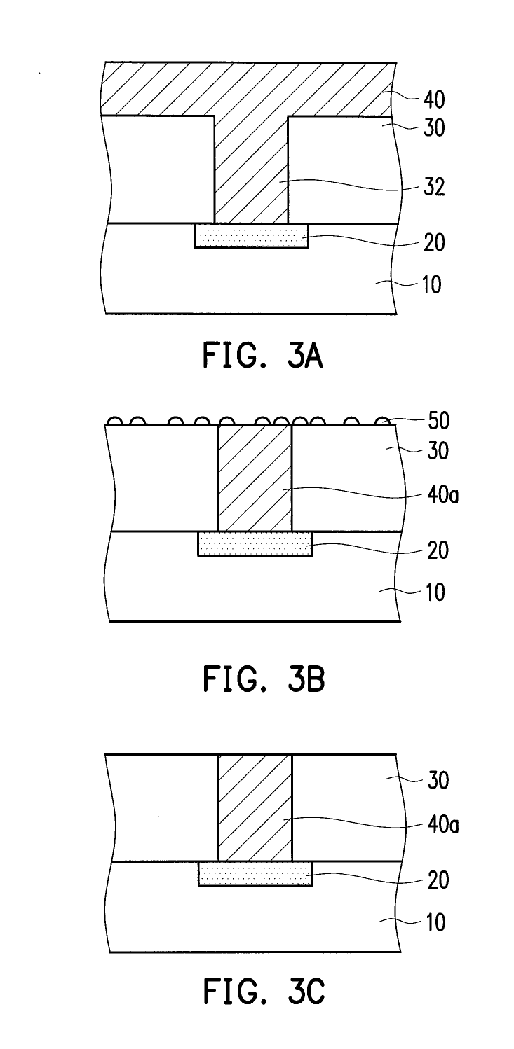

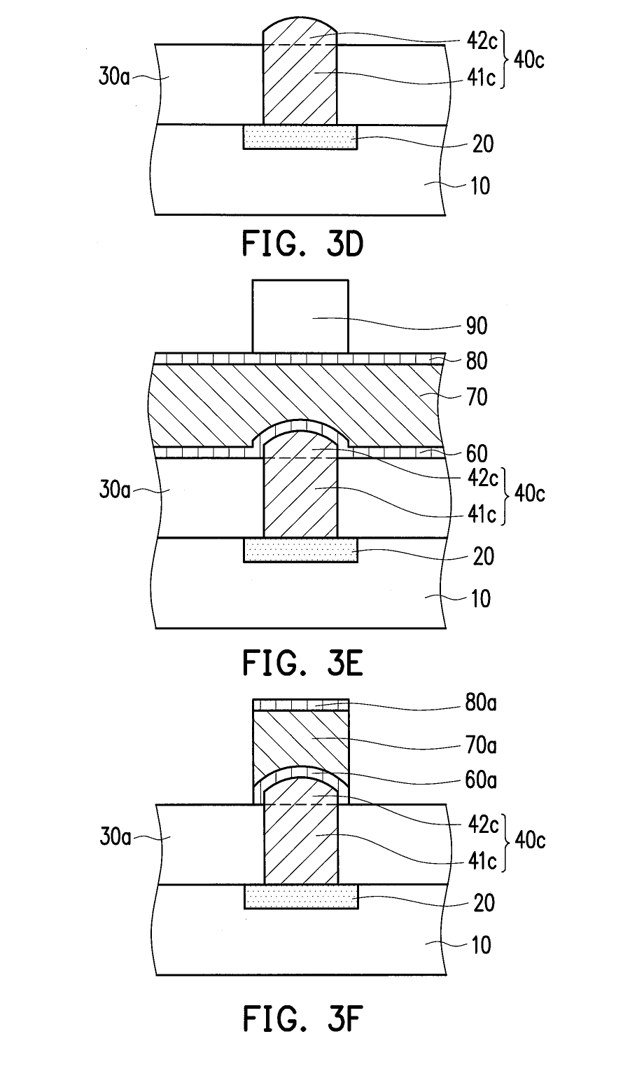

FIG. 3A to FIG. 3F illustrate schematic diagrams of a process of a method of fabricating an interconnect according to yet another embodiment of the invention.

In the present embodiment, the steps and conditions of FIG. 3A to FIG. 3C are the same as the steps and conditions of FIG. 1A to FIG. 1C and are not repeated herein. In the present embodiment, in comparison to the previous embodiments, the duration of the second CMP process is, for instance, greater than that of the previous embodiments. In an embodiment, the duration of the second CMP process is between, for instance, 20 seconds and 60 seconds. Referring to FIG. 3D, the second CMP process described above is performed to remove a portion of the dielectric layer 30, leaving a dielectric layer 30a. After the second CMP process is performed, the conductive plug 40a is formed into a conductive plug 40c.

FIG. 6 is a schematic diagram of the protrusion of a conductive plug according to another embodiment of the invention.

Referring to FIG. 6, the conductive plug 40c includes a body 41c and a protrusion 42c. The body 41c is located in the dielectric layer 30a, and the protrusion 42c is located on the body 41c and protrudes beyond the dielectric layer 30a. The top surface of the protrusion 42c is, for instance, dome shaped. The protrusion 42c of the conductive plug 40c has a sidewall in addition to a top surface, as shown in FIG. 3D. The aspect ratio and an inclination angle θ of the protrusion 42c depend directly on the duration of the CMP process. In particular, the inclination angle θ is the angle between the top surface of the protrusion 42c and the surface level of the dielectric layer 30a at which the protrusion 42c occurs. The longer the duration of the CMP process, the greater the inclination angle θ and the aspect ratio of the protrusion 42c. In an embodiment, the inclination angle θ of the protrusion 42c is, for instance, 90 degrees, and the aspect ratio of the protrusion 42c is ranged from, for instance, 0.15 to 0.45.

Next, referring to FIG. 3E and FIG. 3F, the first barrier layer 60a, the conductive line 70a, and the second barrier layer 80a are formed on the conductive plug 40c in sequence from the bottom up to electrically connect the conductive plug 40c. The direction of extension of the conductive line 70a is, for instance, perpendicular to the direction of extension of the conductive plug 40b. The forming method of each of the first barrier layer 60a, the conductive line 70a, and the second barrier layer 80a is as described above and is not repeated herein. The formed first barrier layer 60a covers the sidewall and the top surface of the conductive plug 40c. The contact area between the conductive plug 40c and the first barrier layer 60a can be increased due to the sidewall of the protrusion 42c of the conductive plug 40c.

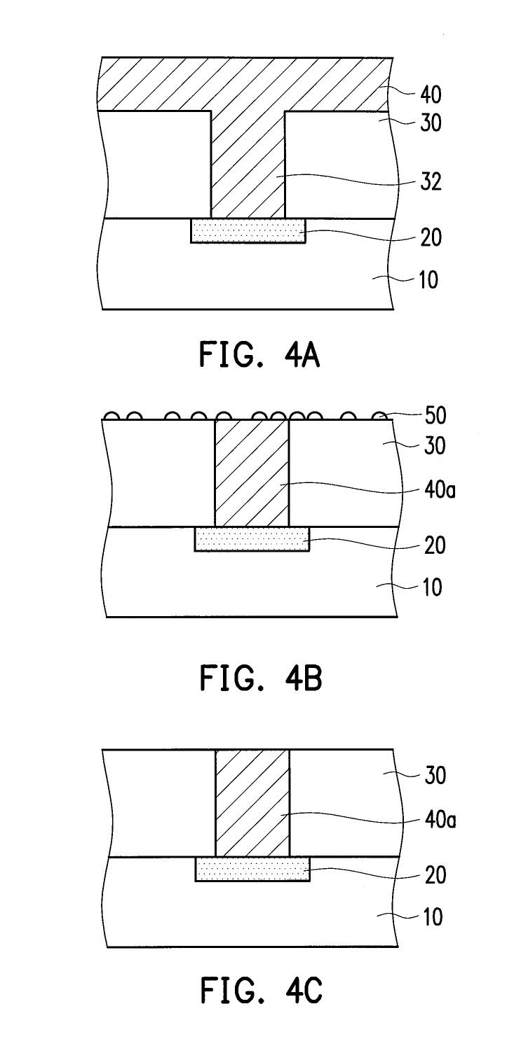

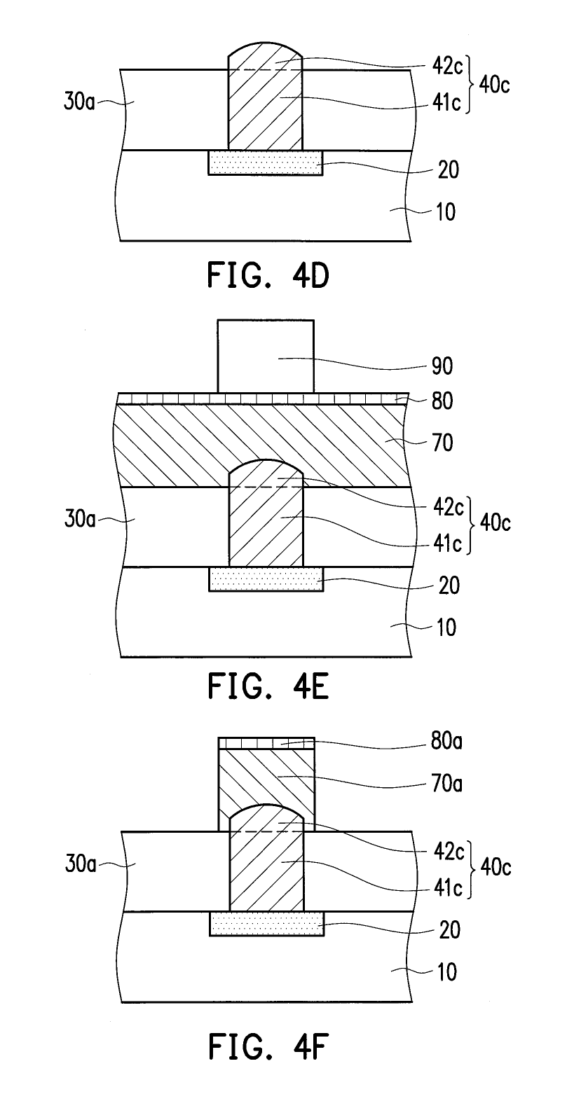

FIG. 4A to FIG. 4F illustrate schematic diagrams of a process of a method of fabricating an interconnect according to still yet another embodiment of the invention.

In the present embodiment, an effect for preventing short-circuit can be further provided. When the first barrier layer 60a is present, the width of the first barrier layer 60a may be greater than the width of the conductive line 70a due to different etching rates of the first barrier layer 60 and the conductive line 70. As a result, two adjacent first barrier layer 60a may come in contact with each other and cause a short-circuit. The steps and conditions of FIG. 4A to FIG. 4D are the same as the steps and conditions of FIG. 3A to FIG. 3D and are not repeated herein. The present embodiment is different from the embodiment of FIG. 3A to FIG. 3F in that in the present embodiment, the first barrier layer 60a is omitted. In other words, in the present embodiment, only the conductive line 70a and the second barrier layer 80a are formed on the conductive plug 40c in sequence from the bottom up as shown in FIG. 4E and FIG. 4F to electrically connect the conductive plug 40c. The direction of extension of the conductive line 70a is, for instance, perpendicular to the direction of extension of the conductive plug 40b. The forming method of each of the conductive line 70a and the second barrier layer 80a is as described above and is not repeated herein. In the present embodiment, the first barrier layer 60a is omitted to prevent a short-circuit between any two adjacent first barrier layer 60a.

Based on the above, the interconnect of the invention includes a conductive plug protruding beyond the dielectric layer. The protrusion of the conductive plug increases the contact area of the conductive plug and allows the conductive plug to be completely covered by the conductive line formed on the conductive plug, thereby preventing the presence of a void between the conductive plug and the conductive line. Moreover, when the conductive plug has better coverage, solvents do not readily seep into the seam of the conductive plug, thereby preventing the occurrence of an electrochemical reaction between the conductive line and the conductive plug. In addition, when a barrier layer is present between the conductive plug and the conductive line, the adhesion between the conductive plug and the conductive line can be improved, and when the barrier layer is omitted, short-circuit between any two conductive lines can be prevented.

Although the invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

1. A method of fabricating an interconnect, comprising:
providing a conductive plug and a dielectric layer, wherein a surface of the conductive plug and the surface of the dielectric layer substantially form a planar surface;
performing a chemical mechanical polishing process to the planar surface, wherein a chemical removal rate of the dielectric layer is greater than a chemical removal rate of the conductive plug, wherein the conductive plug forms a protrusion beyond the dielectric layer after the chemical mechanical polishing process is performed, and the protrusion comprises a top surface and a sidewall;
forming a conductive line on the conductive plug to electrically connect the conductive plug; and
forming a barrier layer between the conductive plug and the conductive line.

2. (canceled)

3. The method of claim 1, wherein an inclination angle of the protrusion is 10 degrees or greater.

4. The method of claim 1, wherein an aspect ratio of the protrusion is ranged from 0.15 to 0.45.

5. (canceled)

6. The method of claim 1, wherein a duration of the chemical mechanical polishing process is 20 seconds or greater.

7. (canceled)

8. A method of fabricating an interconnect, comprising:
forming a hole in a dielectric layer;
forming a conductive layer on the dielectric layer filling the hole;
performing a first chemical mechanical polishing process to the first conductive layer so as to form a conductive plug in the dielectric layer, wherein a surface of the conductive plug and a surface of the dielectric layer substantially form a planar surface, wherein a chemical removal rate of the dielectric layer is lower than a chemical removal rate of the conductive layer;
performing a second chemical mechanical polishing process to the planar surface so that the conductive plug forms a protrusion beyond the dielectric layer, wherein a chemical removal rate of the dielectric layer is greater than a chemical removal rate of the conductive plug, wherein the protrusion comprises a top surface and a sidewall;
forming a conductive line on the conductive plug to electrically connect the conductive plug; and
forming a barrier layer between the conductive plug and the conductive line.

9. The method of claim 8, wherein an inclination angle of the protrusion is 10 degrees or greater.

10. The method of claim 8, wherein an aspect ratio of the protrusion is ranged from 0.15 to 0.45.

11. (canceled)

12. The method of claim 8, wherein a duration of the second chemical mechanical polishing process is 20 seconds or greater.

13. (canceled)

14. An interconnect, comprising:
a dielectric layer;
a conductive plug disposed in the dielectric layer, wherein the conductive plug has a protrusion beyond the dielectric layer, wherein an inclination angle of the protrusion is 10 degrees or greater, and the protrusion comprises a top surface and a sidewall;
a conductive line disposed on and being electrically connected to the conductive plug; and
a barrier layer disposed between the conductive plug and the conductive line.

15. The interconnect of claim 14, wherein an aspect ratio of the protrusion is ranged from 0.15 to 0.45.

16. (canceled)

17. The interconnect of claim 14, wherein a material of the conductive plug comprises tungsten, copper, polysilicon or aluminum.

18. The interconnect of claim 14, wherein a material of the conductive line comprises aluminum, copper, or an alloy thereof.

19. (canceled)

20. The interconnect of claim 14, wherein a material of the barrier layer comprises a metallic material.
